(19) United States
(12) Patent Application Publication
(10) Pub. No.: US 2024/0363547 A1
(43) Pub. Date: Oct. 31, 2024

(54) CHIP PACKAGE STRUCTURE WITH ANTI-WARPAGE STRUCTURE AND METHOD FOR FORMING THE SAME

(71) Applicant: Taiwan Semiconductor Manufacturing Company, Ltd., Hsinchu (TW)

(72) Inventors: Chien-Yuan HUANG, Hsinchu (TW); Chuei-Tang Wang, Taichung City (TW); Shih-Chang Ku, Taipei City (TW)

(73) Assignee: Taiwan Semiconductor Manufacturing Company, Ltd., Hsinchu (TW)

(21) Appl. No.: 18/308,866

(22) Filed: Apr. 28, 2023

(51) Int. Cl. H01L 23/00; H01L 23/367; H01L 25/00; H01L 25/065

(52) U.S. Cl. CPC H01L 23/562; H01L 23/367; H01L 25/0655; H01L 25/50; H01L 23/49816; H01L 24/16; H01L 24/32; H01L 24/73; H01L 2224/16225; H01L 2224/32245; H01L 2224/73253

(57) ABSTRACT

A chip package structure is provided. The chip package structure includes a wiring substrate. The chip package structure includes a chip package over and electrically connected to the wiring substrate. The chip package structure includes a first anti-warpage structure bonded to the wiring substrate. The first anti-warpage structure is made of a semiconductor material and electrically insulated from a wiring structure of the wiring substrate and the chip package. The chip package structure includes a heat dissipation structure over the wiring substrate and surrounding the chip package and the first anti-warpage structure.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1D are cross-sectional views of various stages of a process for forming a chip package structure, in accordance with some embodiments.

FIGS. 1A-1 to 1D-1 are top views of the chip package structure of FIGS. 1A-1D, in accordance with some embodiments.

FIG. 2A is a cross-sectional view of a chip package structure, in accordance with some embodiments.

FIG. 2B is a top view of the chip package structure of FIG. 2A, in accordance with some embodiments.

FIG. 3A is a cross-sectional view of a chip package structure, in accordance with some embodiments.

FIG. 3B is a top view of the chip package structure of FIG. 3A, in accordance with some embodiments.

FIG. 4A is a cross-sectional view of a chip package structure, in accordance with some embodiments.

FIG. 4B is a top view of the chip package structure of FIG. 4A, in accordance with some embodiments.

FIG. 5A is a top view of a chip package structure, in accordance with some embodiments.

FIG. 5B is a cross-sectional view illustrating the chip package structure along a sectional line I-I′ in FIG. 5A, in accordance with some embodiments.

FIG. 5C is a cross-sectional view illustrating the chip package structure along a sectional line II-II′ in FIG. 5A, in accordance with some embodiments.

FIG. 5D is a cross-sectional view illustrating the chip package structure along a sectional line III-III′ in FIG. 5A, in accordance with some embodiments.

FIG. 5E is a cross-sectional view illustrating the chip package structure along a sectional line IV-IV′ in FIG. 5A, in accordance with some embodiments.

FIG. 5F is a cross-sectional view illustrating the chip package structure along a sectional line V-V′ in FIG. 5A, in accordance with some embodiments.

FIG. 5G is a cross-sectional view illustrating the chip package structure along a sectional line VI-VI′ in FIG. 5A, in accordance with some embodiments.

FIG. 6A is a top view of a chip package structure, in accordance with some embodiments.

FIG. 6B is a cross-sectional view illustrating the chip package structure along a sectional line I-I′ in FIG. 6A, in accordance with some embodiments.

FIG. 6C is a cross-sectional view illustrating the chip package structure along a sectional line II-II′ in FIG. 6A, in accordance with some embodiments.

FIG. 7A is a cross-sectional view of a chip package structure, in accordance with some embodiments.

FIG. 7B is a top view of the chip package structure of FIG. 7A, in accordance with some embodiments.

FIG. 8A is a cross-sectional view of a chip package structure, in accordance with some embodiments.

FIG. 8B is a top view of the chip package structure of FIG. 8A, in accordance with some embodiments.

FIG. 9A is a cross-sectional view of a chip package structure, in accordance with some embodiments.

FIG. 9B is a top view of the chip package structure of FIG. 9A, in accordance with some embodiments.

FIG. 10A is a cross-sectional view of a chip package structure, in accordance with some embodiments.

FIG. 10B is a top view of the chip package structure of FIG. 10A, in accordance with some embodiments.

FIG. 11A is a top view of a chip package structure, in accordance with some embodiments.

FIG. 11B is a cross-sectional view illustrating the chip package structure along a sectional line I-I′ in FIG. 11A, in accordance with some embodiments.

FIG. 11C is a cross-sectional view illustrating the chip package structure along a sectional line II-II′ in FIG. 11A, in accordance with some embodiments.

FIG. 11D is a cross-sectional view illustrating the chip package structure along a sectional line III-III′ in FIG. 11A, in accordance with some embodiments.

FIG. 11E is a cross-sectional view illustrating the chip package structure along a sectional line IV-IV′ in FIG. 11A, in accordance with some embodiments.

FIG. 11F is a cross-sectional view illustrating the chip package structure along a sectional line V-V′ in FIG. 11A, in accordance with some embodiments.

FIG. 11G is a cross-sectional view illustrating the chip package structure along a sectional line VI-VI′ in FIG. 11A, in accordance with some embodiments.

FIG. 12A is a top view of a chip package structure, in accordance with some embodiments.

FIG. 12B is a cross-sectional view illustrating the chip package structure along a sectional line I-I′ in FIG. 12A, in accordance with some embodiments.

FIG. 12C is a cross-sectional view illustrating the chip package structure along a sectional line II-II′ in FIG. 12A, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

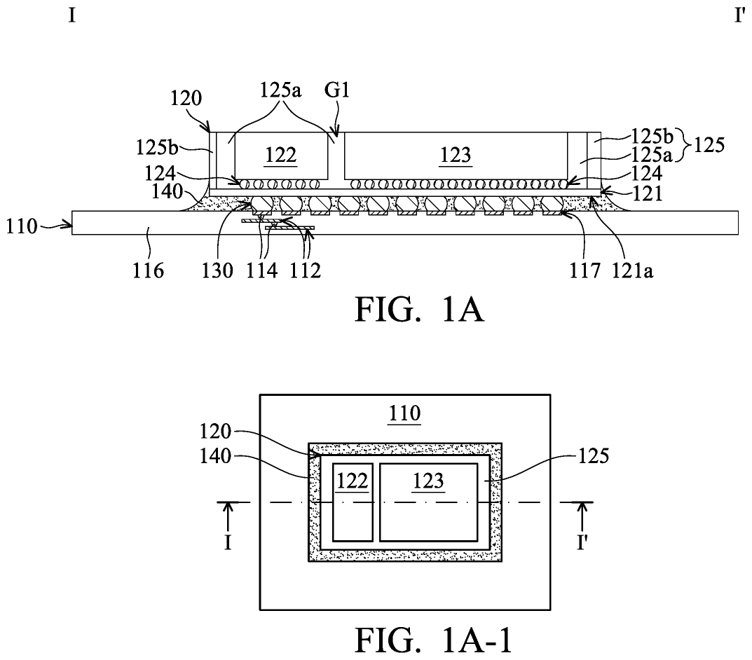

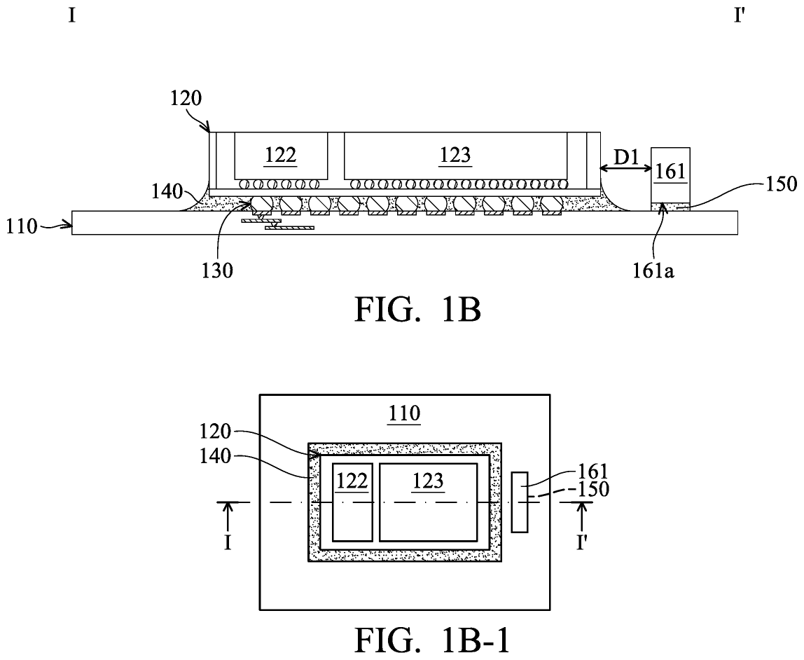

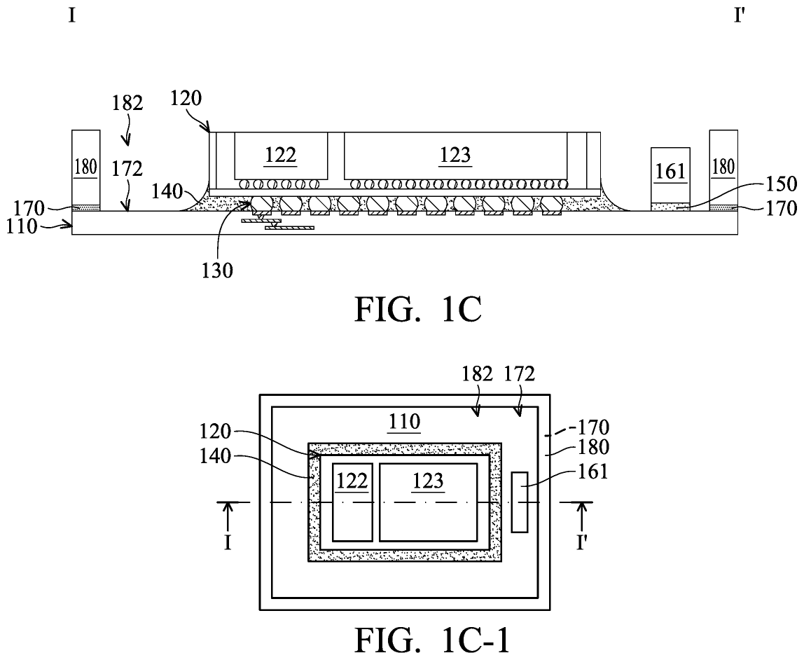

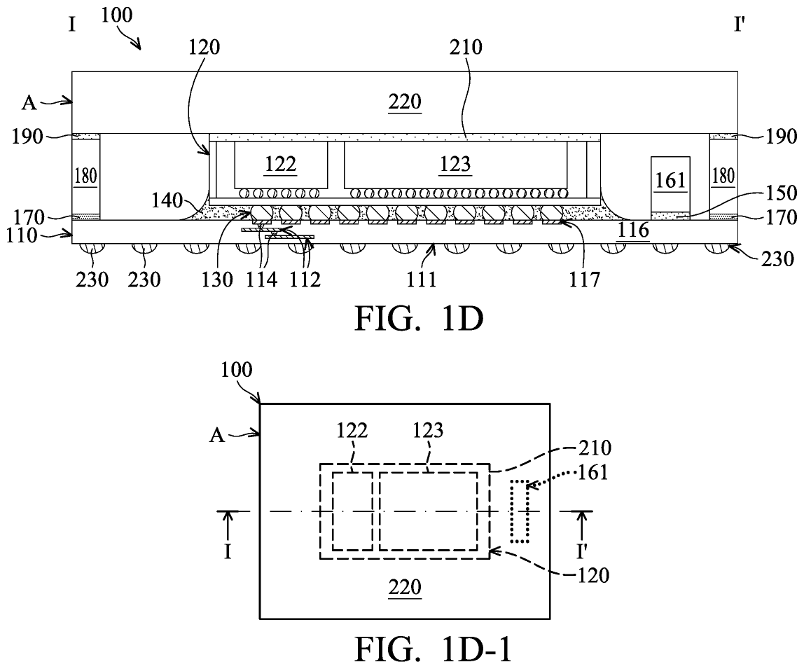

FIGS. 1A-1D are cross-sectional views of various stages of a process for forming a chip package structure, in accordance with some embodiments. FIGS. 1A-1 to 1D-1 are top views of the chip package structure of FIGS. 1A-1D, in accordance with some embodiments. FIGS. 1A-1D are cross-sectional views illustrating the semiconductor device structure along a sectional line I-I′ in FIGS. 1A-1 to 1D-1, in accordance with some embodiments.

As shown in FIGS. 1A and 1A-1, a wiring substrate 110 is provided, in accordance with some embodiments. The wiring substrate 110 includes wiring layers 112, conductive vias 114, a dielectric layer 116, and bonding pads 117, in accordance with some embodiments. The wiring layers 112 and the conductive vias 114 are formed in the dielectric layer 116, in accordance with some embodiments.

The bonding pads 117 are over the dielectric layer 116, in accordance with some embodiments. As shown in FIG. 1A, the conductive vias 114 are electrically connected between different wiring layers 112 and between the wiring layers 112 and the bonding pads 117, in accordance with some embodiments. For the sake of simplicity, FIG. 1A only shows two of the wiring layers 112, in accordance with some embodiments.

The dielectric layer 116 is made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments.

The dielectric layer 116 is formed using deposition processes (e.g. chemical vapor deposition processes or physical vapor deposition processes), photolithography processes, and etching processes, in accordance with some embodiments.

The wiring layers 112 are made of a conductive material, such as metal (e.g. copper, aluminum, or tungsten) or alloys thereof, in accordance with some embodiments. The conductive vias 114 are made of a conductive material, such as metal (e.g. copper, aluminum, or tungsten) or alloys thereof, in accordance with some embodiments. The conductive pads 117 are made of a conductive material, such as metal (e.g. copper, aluminum, or tungsten) or alloys thereof, in accordance with some embodiments.

In some embodiments, the conductive pads 117, the wiring layers 112, and the conductive vias 114 are made of the same material. In some other embodiments. the conductive pads 117, the wiring layers 112, and the conductive vias 114 are made of different materials.

As shown in FIGS. 1A and 1A-1, a chip package 120 is provided, in accordance with some embodiments. The chip package 120 includes an interposer substrate 121, chips 122 and 123, conductive bumps 124, an underfill layer 125a, and a molding layer 125b, in accordance with some embodiments.

The interposer substrate 121 includes a semiconductor substrate (not shown), two interconnect structures (not shown) over and under the semiconductor substrate, and conductive vias (not shown) passing through the semiconductor substrate, in accordance with some embodiments.

Each interconnect structure includes wiring layers, conductive vias, bonding pads, and a dielectric layer, in accordance with some embodiments. The wiring layers and the conductive vias are formed in the dielectric layer, in accordance with some embodiments. The bonding pads are over the dielectric layer, in accordance with some embodiments. The conductive vias are electrically connected between different wiring layers and the bonding pads, in accordance with some embodiments.

The dielectric layer is made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments.

The dielectric layer is formed using deposition processes (e.g. chemical vapor deposition processes or physical vapor deposition processes), photolithography processes, and etching processes, in accordance with some embodiments. The wiring layers, the conductive vias and the bonding pads are made of a conductive material, such as metal (e.g. copper, aluminum, or tungsten) or alloys thereof, in accordance with some embodiments.

The chips 122 and 123 are bonded to the bonding pads of the interposer substrate 121 through the conductive bumps 124, in accordance with some embodiments. The chips 122 and 123 are spaced apart from each other by a gap G1, in accordance with some embodiments. The chips 122 and 123 may be different chips with different functions.

The conductive bumps 124 are physically and electrically connected between the chips 122 and 123 and the interposer substrate 121, in accordance with some embodiments. The chips 122 and 123 include a system on chip (SoC), a high performance computing (HPC) chip, or another suitable chip.

Each of the chips 122 and 123 includes a semiconductor substrate and an interconnect structure over the semiconductor substrate, in accordance with some embodiments. In some embodiments, the semiconductor substrate is made of an elementary semiconductor material including silicon or germanium in a single crystal structure, a polycrystal structure, or an amorphous structure.

In some other embodiments, the semiconductor substrate is made of a compound semiconductor, such as silicon carbide, gallium arsenide, gallium phosphide, indium phosphide, indium arsenide, an alloy semiconductor, such as SiGe, or GaAsP, or a combination thereof. The semiconductor substrate may also include multi-layer semiconductors, semiconductor on insulator (SOI) (such as silicon on insulator or germanium on insulator), or a combination thereof.

In some embodiments, the semiconductor substrate includes various device elements. In some embodiments, the various device elements are formed in and/or over the semiconductor substrate. The device elements are not shown in figures for the purpose of simplicity and clarity.

Examples of the various device elements include active devices, passive devices, other suitable elements, or a combination thereof. The active devices may include transistors or diodes (not shown) formed at a surface of the semiconductor substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate. The isolation features are used to define active regions and electrically isolate various device elements formed in and/or over the semiconductor substrate in the active regions. In some embodiments, the isolation features include shallow trench isolation (STI) features, local oxidation of silicon (LOCOS) features, other suitable isolation features, or a combination thereof.

The conductive bumps 124 are made of a conductive material such as copper (Cu), aluminum (Al), tungsten (W), cobalt (Co), nickel (Ni), or tin (Sn), in accordance with some embodiments. The conductive bumps 124 are formed using a plating process such as an electroplating process, in accordance with some embodiments.

The chip package 120 is formed using a Chip-on-Wafer-on-Substrate (CoWoS) process, in accordance with some embodiments. The chip package 120 is a CoWoS-S (Chip-on-Wafer-on-Substrate Silicon substrate) type chip package, though the application is not limited thereto. The chip package 120 may be other types of chip packages. For example, the interposer substrate 121 is replaced with a redistribution substrate to form a CoWoS-R (Chip-on-Wafer-on-Substrate Redistribution) type chip package. In some embodiments, a chip (not shown) is formed in the redistribution substrate to form a CoWoS-L (Chip-on-Wafer-on-Substrate LSI) type chip package. In some embodiments, the chip package 120 is replaced with an integrated fan-out (InFO) chip package.

As shown in FIG. 1A, the underfill layer 125a is formed between the chips 122 and 123 and the interposer substrate 121, in accordance with some embodiments. The underfill layer 125a surrounds the conductive bumps 124 and the chips 122 and 123, in accordance with some embodiments.

The underfill layer 125a extends into the gap G1, in accordance with some embodiments. The gap G1 is filled with the underfill layer 125a, in accordance with some embodiments. The underfill layer 125a is made of an insulating material, such as a polymer material, in accordance with some embodiments.

As shown in FIG. 1A, the molding layer 125b is formed over the interposer substrate 121, in accordance with some embodiments. The molding layer 125b surrounds the chips 122 and 123, the conductive bumps 124, and the underfill layer 125a, in accordance with some embodiments.

The molding layer 125b is made of an insulating material, such as a polymer material (e.g., epoxy), in accordance with some embodiments. The molding layer 125b and the underfill layer 125a are made of different materials, in accordance with some embodiments. The molding layer 125b and the underfill layer 125a together form an insulating structure 125, in accordance with some embodiments.

As shown in FIG. 1A, solder bumps 130 are formed over a bottom surface 121a of the interposer substrate 121, in accordance with some embodiments. The solder bumps 130 are made of tin (Sn) or another suitable conductive material, in accordance with some embodiments. The solder bumps 130 are formed using a plating process such as an electroplating process, in accordance with some embodiments.

As shown in FIGS. 1A and 1A-1, the chip package 120 is bonded to the wiring substrate 110 through the solder bumps 130, in accordance with some embodiments. The chip package 120 is electrically connected to the wiring substrate 110 through the solder bumps 130, in accordance with some embodiments. The solder bumps 130 are bonded to the bonding pads 117 of the wiring substrate 110, in accordance with some embodiments.

As shown in FIGS. 1B and 1B-1, an underfill layer 140 is formed between the chip package 120 and the wiring substrate 110, in accordance with some embodiments. The underfill layer 140 surrounds the solder bumps 130 and the chip package 120, in accordance with some embodiments. The underfill layer 140 is made of an insulating material, such as a polymer material, in accordance with some embodiments.

As shown in FIGS. 1B and 1B-1, an adhesive layer 150 is formed over the wiring substrate 110, in accordance with some embodiments. The adhesive layer 150 is made of a polymer material such as epoxy or silicone, in accordance with some embodiments.

As shown in FIGS. 1B and 1B-1, an anti-warpage structure 161 is bonded to the wiring substrate 110 through the adhesive layer 150, in accordance with some embodiments. The adhesive layer 150 is between the anti-warpage structure 161 and the wiring substrate 110, in accordance with some embodiments. The anti-warpage structure 161 is electrically insulated from the wiring substrate 110 and the chip package 120, in accordance with some embodiments.

The anti-warpage structure 161 has a semiconductor bottom surface 161a, and the adhesive layer 150 is in contact with the semiconductor bottom surface 161a, in accordance with some embodiments. In some embodiments, a distance D1 between the anti-warpage structure 161 and the chip package 120 ranges from about 500 μm to about 2000 μm.

If the distance D1 is greater than 2000 μm, the distance D1 is too large and therefore it is difficult to reduce the size of the overall chip package structure, in accordance with some embodiments. If the distance D1 is less than 500 μm, the distance D1 is too small, so the anti-warpage structure 161 and the chip package 120 may interfere with each other, in accordance with some embodiments.

The anti-warpage structure 161 is made of a semiconductor material, in accordance with some embodiments. The entire anti-warpage structure 161 is made of a semiconductor material, in accordance with some embodiments. The semiconductor material includes an elementary semiconductor material including silicon or germanium in a single crystal structure, a polycrystal structure, or an amorphous structure.

In some other embodiments, the anti-warpage structure 161 is made of a compound semiconductor, such as silicon carbide, gallium arsenide, gallium phosphide, indium phosphide, indium arsenide, an alloy semiconductor, such as SiGe, or GaAsP, or a combination thereof. The anti-warpage structure 161 may also include multi-layer semiconductors, semiconductor on insulator (SOI) (such as silicon on insulator or germanium on insulator), or a combination thereof.

If the anti-warpage structure 161 is made of a semiconductor material, the thermal expansion coefficient of the anti-warpage structure 161 is similar to or substantially equal to the semiconductor substrates of the chips 122 and 123, which reduces the difference between the thermal expansion coefficients of the anti-warpage structure 161 and the chips 122 and 123 and therefore reduces the warpage of the wiring substrate 110, in accordance with some embodiments.

In some other embodiments, the anti-warpage structure 161 is made of a material with a thermal expansion coefficient lower than that of the wiring substrate 110. For example, the anti-warpage structure 161 is made of metal, in accordance with some embodiments.

As shown in FIGS. 1C and 1C-1, an adhesive layer 170 is formed over the wiring substrate 110, in accordance with some embodiments. The adhesive layer 170 has an opening 172, in accordance with some embodiments. The chip package 120 is in the opening 172, in accordance with some embodiments. The adhesive layer 170 is made of a polymer material such as epoxy or silicone, in accordance with some embodiments.

As shown in FIGS. 1C and 1C-1, a ring structure 180 is disposed over the adhesive layer 170, in accordance with some embodiments. As shown in FIGS. 1C and 1C-1, the ring structure 180 has an opening 182, in accordance with some embodiments. The opening 182 have a substantially rectangular shape, in accordance with some embodiments.

As shown in FIGS. 1C and 1C-1, the opening 172 of the adhesive layer 170 is under the opening 182, in accordance with some embodiments. As shown in FIGS. 1C and 1C-1, the chip package 120 is in the opening 182, in accordance with some embodiments. The ring structure 180 surrounds the chip package 120 and the anti-warpage structure 161, in accordance with some embodiments.

The ring structure 180 is made of a rigid material, such as metal (e.g., copper or iron), alloys thereof (e.g., stainless steel), or another suitable material which is more rigid than the wiring substrate 110, in accordance with some embodiments. The ring structure 180 is made of a high-heat-conductivity material, such as metal, in accordance with some embodiments.

As shown in FIGS. 1D and 1D-1, an adhesive layer 190 is formed over the ring structure 180, in accordance with some embodiments. The adhesive layer 190 is made of a polymer material such as epoxy or silicone, in accordance with some embodiments.

As shown in FIGS. 1D and 1D-1, an adhesive layer 210 is formed over the chip package 120, in accordance with some embodiments. The adhesive layer 210 is made of a polymer material, such as epoxy or silicone, and a high-heat-conductivity material, in accordance with some embodiments. The high-heat-conductivity material includes a metal material, such as silver, gold, or another suitable material.

As shown in FIGS. 1D and 1D-1, a lid 220 is disposed over the adhesive layers 190 and 210, in accordance with some embodiments. The lid 220 is made of a rigid material, such as metal (e.g., copper or iron), alloys thereof (e.g., stainless steel), or another suitable material which is more rigid than the wiring substrate 110, in accordance with some embodiments.

The lid 220 is made of a high-heat-conductivity material, such as metal, in accordance with some embodiments. The ring structure 180, the adhesive layer 190, and the lid 220 together form a heat dissipation structure A, in accordance with some embodiments.

As shown in FIGS. 1D and 1D-1, solder bumps 230 are formed over a bottom surface 111 of the wiring substrate 110, in accordance with some embodiments. The solder bumps 230 are electrically connected to the wiring layers 112 and the conductive vias 114, in accordance with some embodiments.

The solder bumps 230 are made of tin (Sn) or another suitable conductive material, in accordance with some embodiments. The solder bumps 230 are formed using a plating process such as an electroplating process, in accordance with some embodiments. In this step, a chip package structure 100 is substantially formed, in accordance with some embodiments.

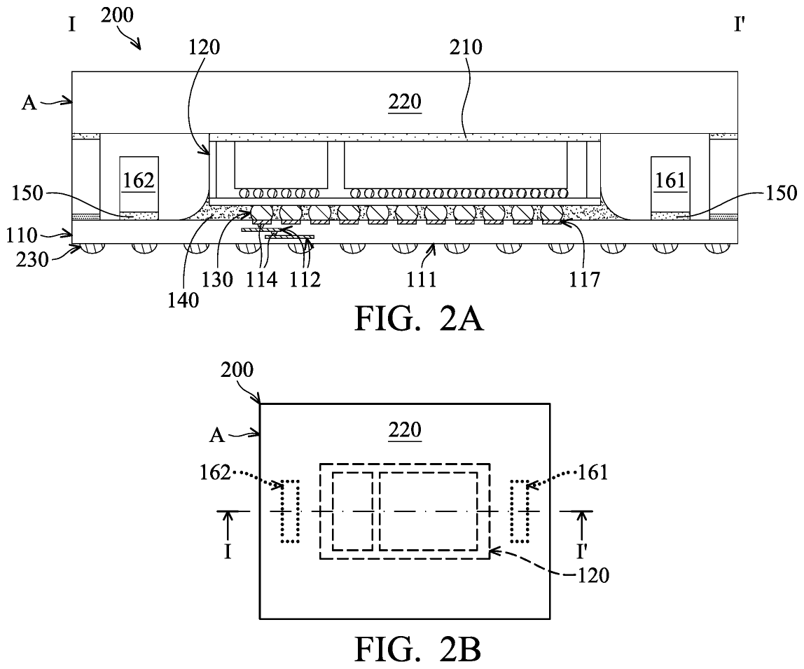

FIG. 2A is a cross-sectional view of a chip package structure 200, in accordance with some embodiments. FIG. 2B is a top view of the chip package structure 200 of FIG. 2A, in accordance with some embodiments. FIG. 2A is a cross-sectional view illustrating the semiconductor device structure 200 along a sectional line I-I′ in FIG. 2B, in accordance with some embodiments.

As shown in FIGS. 2A and 2B, the chip package structure 200 is similar to the chip package structure 100 of FIGS. 1D and 1D-1, except that the chip package structure 200 further includes an anti-warpage structure 162, in accordance with some embodiments. The anti-warpage structure 162 is bonded to the wiring substrate 110 through the adhesive layer 150, in accordance with some embodiments.

The anti-warpage structure 162 is spaced apart from the anti-warpage structure 161, in accordance with some embodiments. In some embodiments, the anti-warpage structures 161 and 162 are on opposite sides of the chip package 120. The anti-warpage structures 161 and 162 are spaced apart from the chip package 120, in accordance with some embodiments. In some embodiments, the anti-warpage structures 161 and 162 have the same thickness.

The anti-warpage structure 162 is made of a semiconductor material, in accordance with some embodiments. The entire anti-warpage structure 162 is made of a semiconductor material, in accordance with some embodiments. The semiconductor material includes an elementary semiconductor material including silicon or germanium in a single crystal structure, a polycrystal structure, or an amorphous structure.

In some other embodiments, the anti-warpage structure 162 is made of a compound semiconductor, such as silicon carbide, gallium arsenide, gallium phosphide, indium phosphide, indium arsenide, an alloy semiconductor, such as SiGe, or GaAsP, or a combination thereof. The anti-warpage structure 162 may also include multi-layer semiconductors, semiconductor on insulator (SOI) (such as silicon on insulator or germanium on insulator), or a combination thereof. In some other embodiments, the anti-warpage structure 162 is made of metal.

In some embodiments, the anti-warpage structures 161 and 162 are made of the same material. In some embodiments, the anti-warpage structures 161 and 162 are made of different materials.

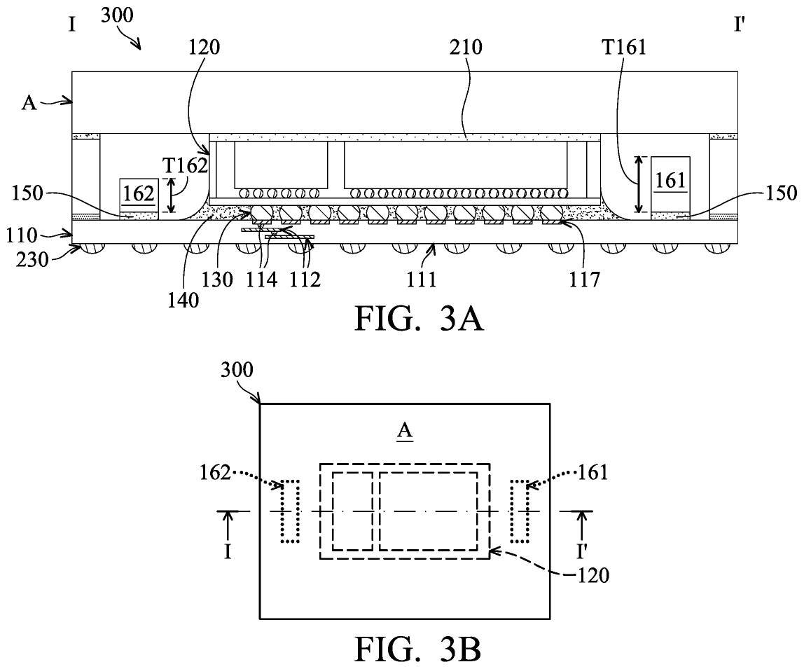

FIG. 3A is a cross-sectional view of a chip package structure 300, in accordance with some embodiments. FIG. 3B is a top view of the chip package structure 300 of FIG. 3A, in accordance with some embodiments. FIG. 3A is a cross-sectional view illustrating the semiconductor device structure 300 along a sectional line I-I′ in FIG. 3B, in accordance with some embodiments.

As shown in FIGS. 3A and 3B, the chip package structure 300 is similar to the chip package structure 200 of FIGS. 2A and 2B, except that a thickness T162 of the anti-warpage structure 162 is less than a thickness T161 of the anti-warpage structure 161 in the chip package structure 300, in accordance with some embodiments.

The anti-warpage ability of the (thick) anti-warpage structure 161 is greater than the (thin) anti-warpage structure 162, in accordance with some embodiments. The anti-warpage structure 161 is disposed over a first portion of the wiring substrate 110, and the first portion is originally prone to large warpage, in accordance with some embodiments. The anti-warpage structure 162 is disposed over a second portion of the wiring substrate 110, and the second portion is originally prone to small warpage, in accordance with some embodiments. Therefore, the arrangement of the anti-warpage structures 161 and 162 may locally reduce the warpage of the wiring substrate 110, which improves the coplanarity of the solder bumps 230, in accordance with some embodiments. The formation of the anti-warpage structures 161 and 162 improves design flexibility, in accordance with some embodiments.

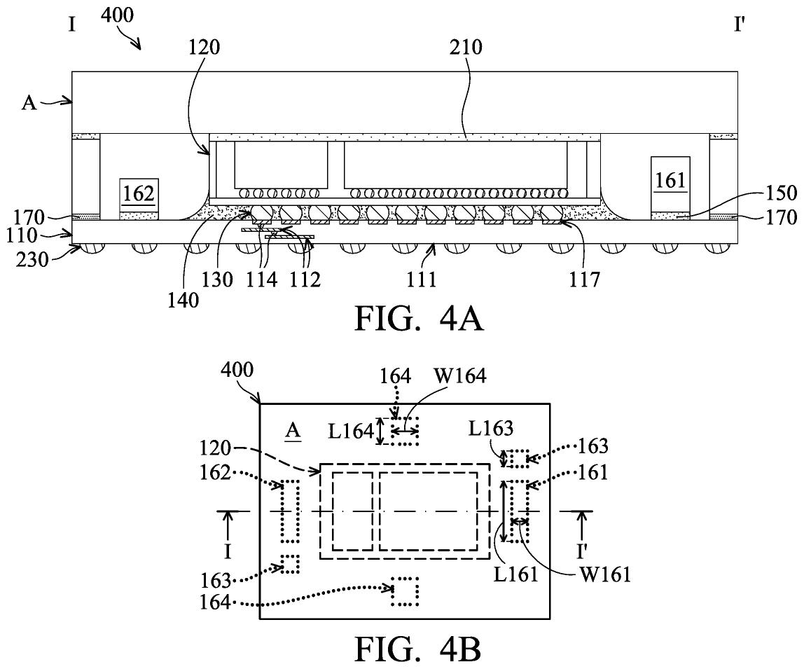

FIG. 4A is a cross-sectional view of a chip package structure 400, in accordance with some embodiments. FIG. 4B is a top view of the chip package structure 400 of FIG. 4A, in accordance with some embodiments. FIG. 4A is a cross-sectional view illustrating the semiconductor device structure 400 along a sectional line I-I′ in FIG. 4B, in accordance with some embodiments.

As shown in FIGS. 4A and 4B, the chip package structure 400 is similar to the chip package structure 300 of FIGS. 3A and 3B, except that the chip package structure 400 further includes anti-warpage structures 163 and 164, in accordance with some embodiments. The sizes of the anti-warpage structures 161 (or 162), 163, and 164 are different from each other, in accordance with some embodiments.

For example, the length L161 of the anti-warpage structure 161 is greater than the length L164 of the anti-warpage structure 164, and the length L164 is greater than the length L163 of the anti-warpage structure 163, in accordance with some embodiments. The width W164 of the anti-warpage structure 164 is greater than the width W161 of the anti-warpage structure 161, in accordance with some embodiments.

The larger the anti-warpage structure, the stronger the anti-warpage ability, in accordance with some embodiments. Therefore, the arrangement of the anti-warpage structures 161, 162, 163 and 164 can be adjusted according to different warpage potential of different portions of the wiring substrate 110 so as to minimize the warpage of the wiring substrate 110, which improves the coplanarity of the solder bumps 230, in accordance with some embodiments. The anti-warpage structures 163 and 164 are made of a semiconductor material or a metal material, in accordance with some embodiments.

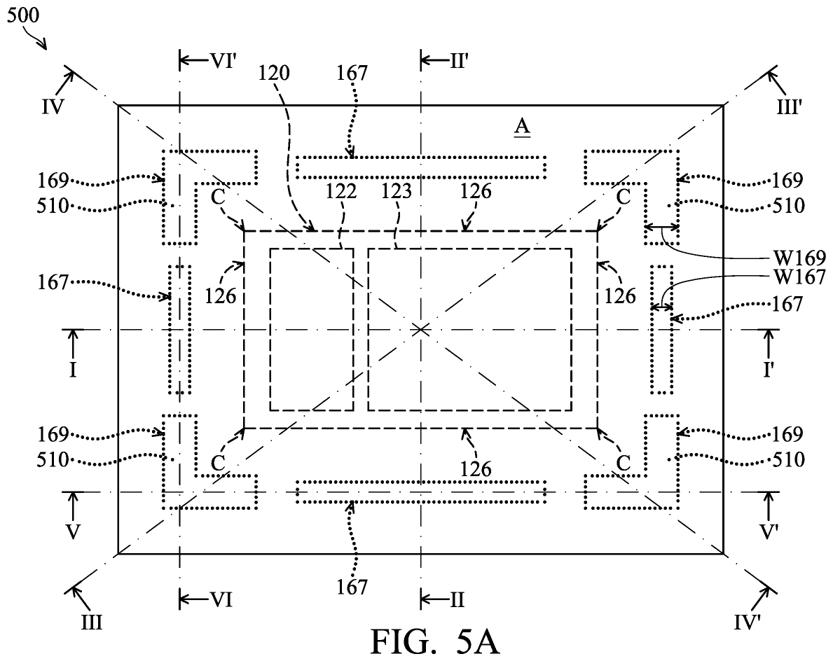

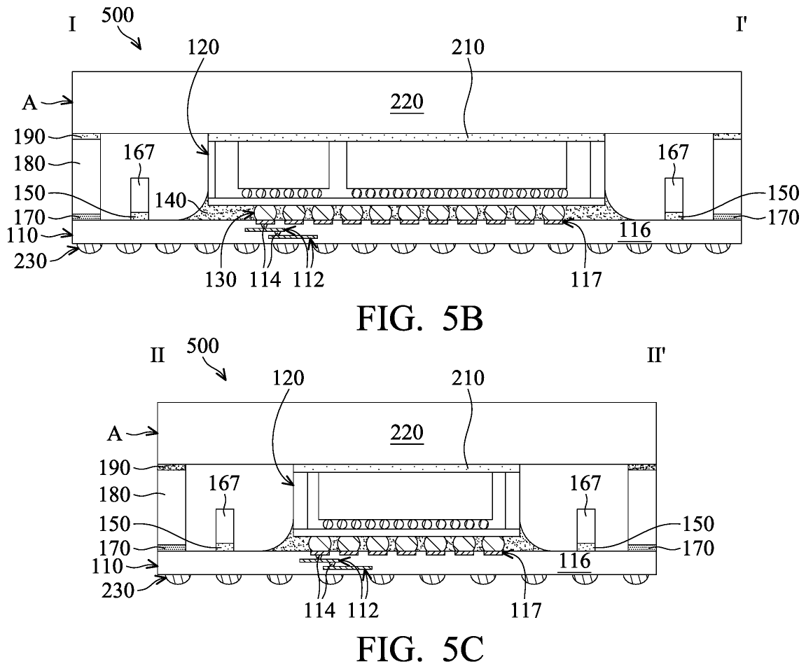

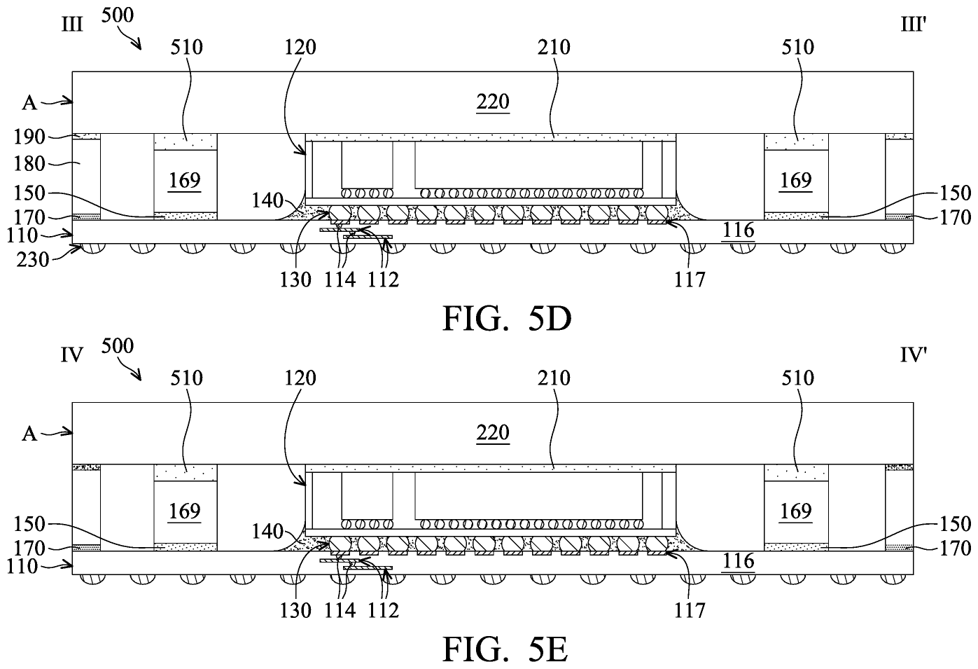

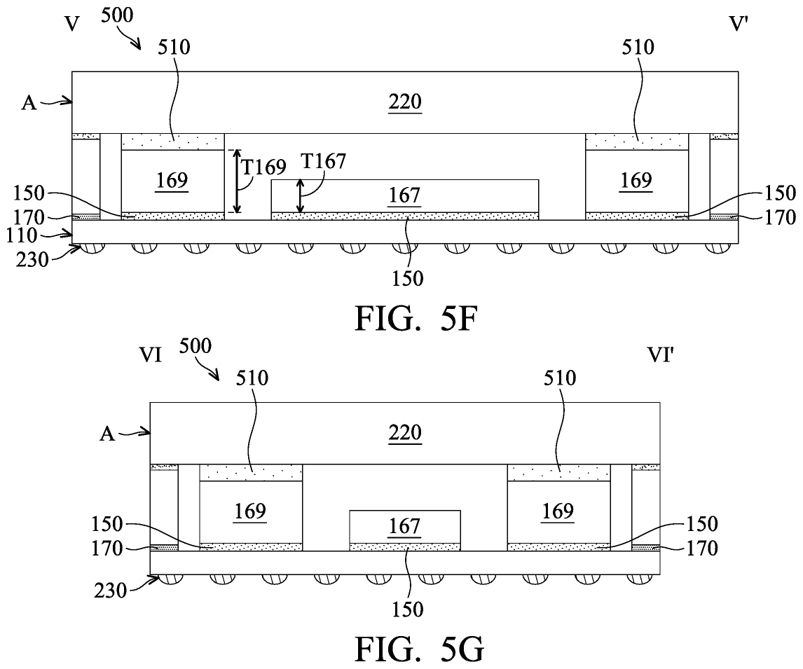

FIG. 5A is a top view of a chip package structure 500, in accordance with some embodiments. FIG. 5B is a cross-sectional view illustrating the chip package structure 500 along a sectional line I-I′ in FIG. 5A, in accordance with some embodiments. FIG. 5C is a cross-sectional view illustrating the chip package structure 500 along a sectional line II-II′ in FIG. 5A, in accordance with some embodiments.

FIG. 5D is a cross-sectional view illustrating the chip package structure 500 along a sectional line III-III′ in FIG. 5A, in accordance with some embodiments. FIG. 5E is a cross-sectional view illustrating the chip package structure 500 along a sectional line IV-IV′ in FIG. 5A, in accordance with some embodiments.

FIG. 5F is a cross-sectional view illustrating the chip package structure 500 along a sectional line V-V′ in FIG. 5A, in accordance with some embodiments. FIG. 5G is a cross-sectional view illustrating the chip package structure 500 along a sectional line VI-VI′ in FIG. 5A, in accordance with some embodiments.

As shown in FIGS. 5A and 5B, the chip package structure 500 is similar to the chip package structure 400 of FIGS. 4A and 4B, except that the chip package structure 500 further includes anti-warpage structures 167 and 169 and an adhesive layer 510 and does not include the anti-warpage structures 161 and 162, in accordance with some embodiments.

The anti-warpage structures 167 are bonded to the wiring substrate 110 through the adhesive layer 150, in accordance with some embodiments. The anti-warpage structures 167 are electrically insulated from the wiring substrate 110 and the chip package 120, in accordance with some embodiments. The anti-warpage structures 167 are made of a material the same as the anti-warpage structures 161 of FIG. 1D, in accordance with some embodiments.

As shown in FIG. 5A, the linewidth W169 of the anti-warpage structure 169 is greater than the linewidth W167 of the anti-warpage structure 167, in accordance with some embodiments. As shown in FIGS. 5B, 5C, 5D, 5E, 5F and 5G, the thickness T169 of the anti-warpage structure 169 is greater than the thickness T167 of the anti-warpage structure 167, in accordance with some embodiments.

Therefore, the anti-warpage structure 169 has greater anti-warpage ability than the anti-warpage structure 167, in accordance with some embodiments. The anti-warpage structures 169 are disposed over portions of the wiring substrate 110, which are originally prone to large warpage, in accordance with some embodiments. The anti-warpage structures 167 are disposed over portions of the wiring substrate 110, which are originally prone to small warpage, in accordance with some embodiments.

As shown in FIG. 5A, the chip package 120 has corner portions C and sidewalls 126, in accordance with some embodiments. The sidewalls 126 are between the corner portions C, in accordance with some embodiments. Since first portions of the wiring substrate 110 adjacent to the sidewalls 126 are originally prone to small warpage, the anti-warpage structures 167 are disposed over the first portions, in accordance with some embodiments.

The anti-warpage structure 167 is between two of the corner portions C, in accordance with some embodiments. The anti-warpage structure 167 extends along the corresponding sidewall 126, in accordance with some embodiments. The anti-warpage structures 167 are spaced apart from the chip package 120, in accordance with some embodiments.

Since the second portions of the wiring substrate 110 adjacent to the corner portions C are originally prone to large warpage, the anti-warpage structures 169 are disposed over the second portions, in accordance with some embodiments. The anti-warpage structures 169 surround the corner portions C respectively, in accordance with some embodiments. The anti-warpage structure 169 has an L-shape, in accordance with some embodiments. The anti-warpage structures 167 and 169 are made of a semiconductor material or a metal material, in accordance with some embodiments.

The adhesive layer 510 is bonded between the anti-warpage structures 169 and the lid 220, in accordance with some embodiments. The formation of the adhesive layer 510 includes: forming the adhesive layer 510 over the anti-warpage structures 169; and bonding the lid 220 to the adhesive layer 510, in accordance with some embodiments.

The adhesive layer 510 is made of a polymer material such as epoxy or silicone, in accordance with some embodiments. The adhesive layer 510 can fix the anti-warpage structures 169 to the lid 220, which improves the anti-warpage ability of the anti-warpage structures 169, in accordance with some embodiments.

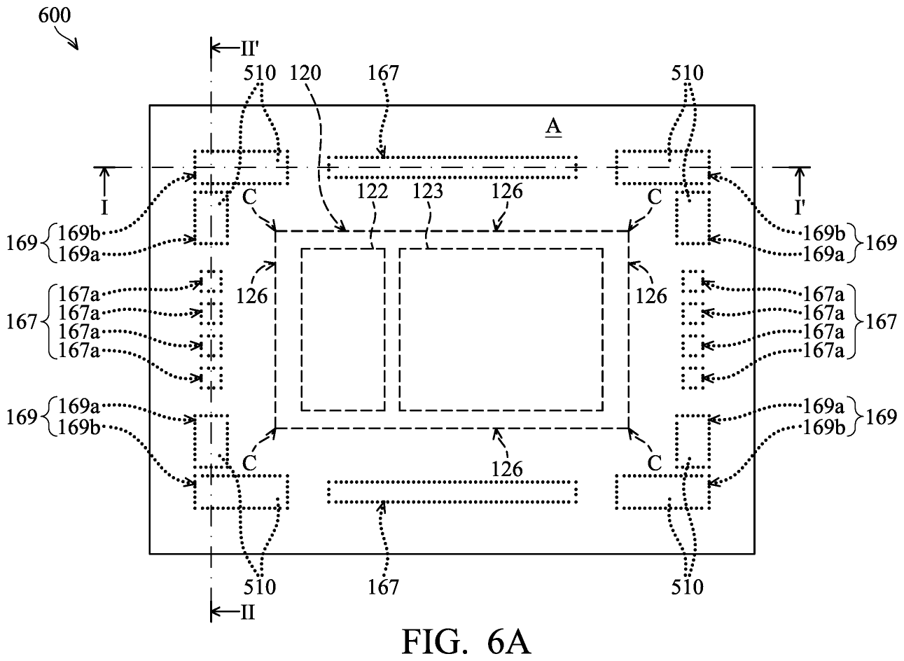

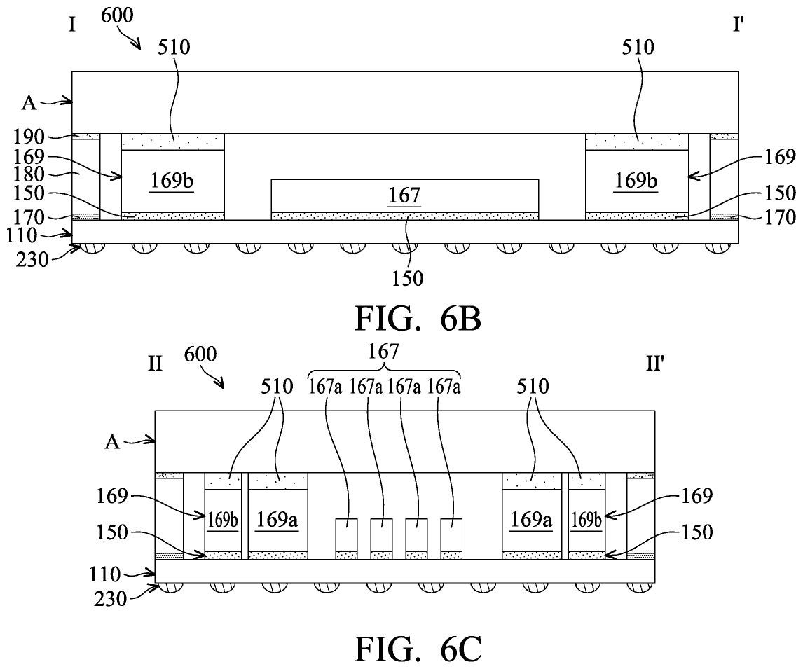

FIG. 6A is a top view of a chip package structure 600, in accordance with some embodiments. FIG. 6B is a cross-sectional view illustrating the chip package structure 600 along a sectional line I-I′ in FIG. 6A, in accordance with some embodiments. FIG. 6C is a cross-sectional view illustrating the chip package structure 600 along a sectional line II-II′ in FIG. 6A, in accordance with some embodiments.

As shown in FIGS. 6A, 6B and 6C, the chip package structure 600 is similar to the chip package structure 500 of FIGS. 5A, 5F and 5G, except that the anti-warpage structure 167 has parts 167a, and the anti-warpage structure 169 has parts 169a and 169b in the chip package structure 600, in accordance with some embodiments.

The parts 167a are spaced apart from each other, in accordance with some embodiments. The parts 167a are arranged along the corresponding sidewall 126 of the chip package 120, in accordance with some embodiments. In one of the anti-warpage structures 169, the parts 169a and 169b are spaced apart from each other, in accordance with some embodiments.

In one of the anti-warpage structures 169, the part 169a extends along one of the sidewalls 126, the part 169b extends along another one of the sidewalls 126, and the one and the another one of the sidewalls 126 meet to form one of the corner portions C, in accordance with some embodiments.

Since it is easy to form a structure having a straight-line shape using a photolithography process and an etching process, it is easy to form the parts 167a, 169a, and 169b and the anti-warpage structure 167 having a straight-line shape, which improves the yield of the parts 167a, 169a, and 169b and the anti-warpage structure 167, in accordance with some embodiments.

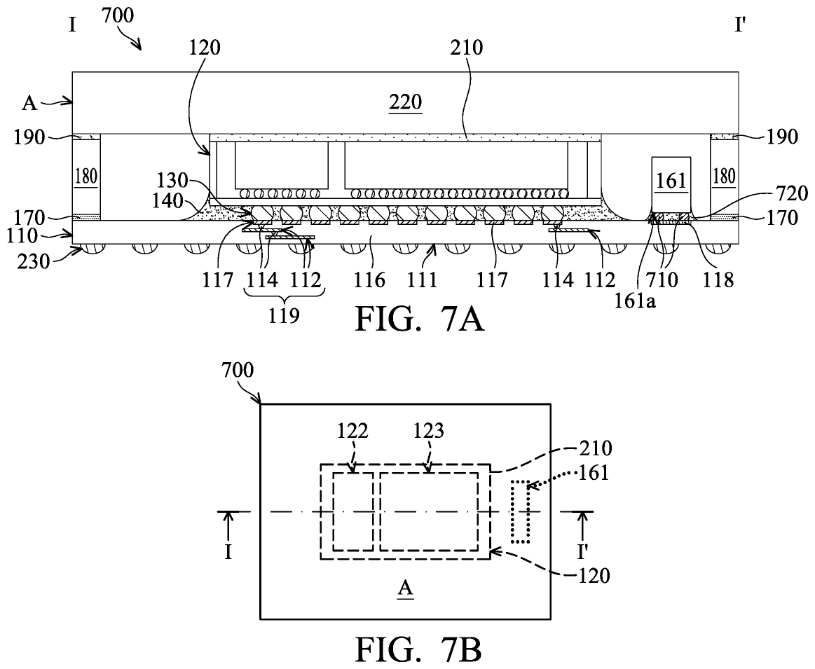

FIG. 7A is a cross-sectional view of a chip package structure 700, in accordance with some embodiments. FIG. 7B is a top view of the chip package structure 700 of FIG. 7A, in accordance with some embodiments. FIG. 7A is a cross-sectional view illustrating the semiconductor device structure 700 along a sectional line I-I′ in FIG. 7B, in accordance with some embodiments.

As shown in FIGS. 7A and 7B, the chip package structure 700 is similar to the chip package structure 100 of FIGS. 1D and 1D-1, except that the chip package structure 700 further includes conductive bumps 710 and an underfill layer 720 and does not include the adhesive layer 150 of the chip package structure 100, in accordance with some embodiments.

The anti-warpage structure 161 is bonded to the wiring substrate 110 through the conductive bumps 710, in accordance with some embodiments. The conductive bumps 710 are between the anti-warpage structure 161 and the wiring substrate 110, in accordance with some embodiments. The conductive bumps 710 are in contact with the semiconductor bottom surface 161a of the anti-warpage structure 161, in accordance with some embodiments.

The wiring substrate 110 further includes a dummy bonding pad 118 over the dielectric layer 116, in accordance with some embodiments. The conductive bumps 710 are bonded to the dummy bonding pad 118, in accordance with some embodiments. The anti-warpage structure 161 is electrically insulated from the chip package 120 and a wiring structure 119 of the wiring substrate 110, in accordance with some embodiments. The wiring structure 119 includes all the wiring layers 112 and all the conductive vias 114 of the wiring substrate 110, in accordance with some embodiments.

The conductive bumps 710 are made of a conductive material such as copper (Cu), aluminum (Al), tungsten (W), cobalt (Co), nickel (Ni), or tin (Sn), in accordance with some embodiments. The conductive bumps 710 are formed using a plating process such as an electroplating process, in accordance with some embodiments.

The underfill layer 720 is between the anti-warpage structure 161 and the wiring substrate 110, in accordance with some embodiments. The underfill layer 720 surrounds the conductive bumps 710 and the anti-warpage structure 161, in accordance with some embodiments. The underfill layer 720 is made of an insulating material, such as a polymer material, in accordance with some embodiments.

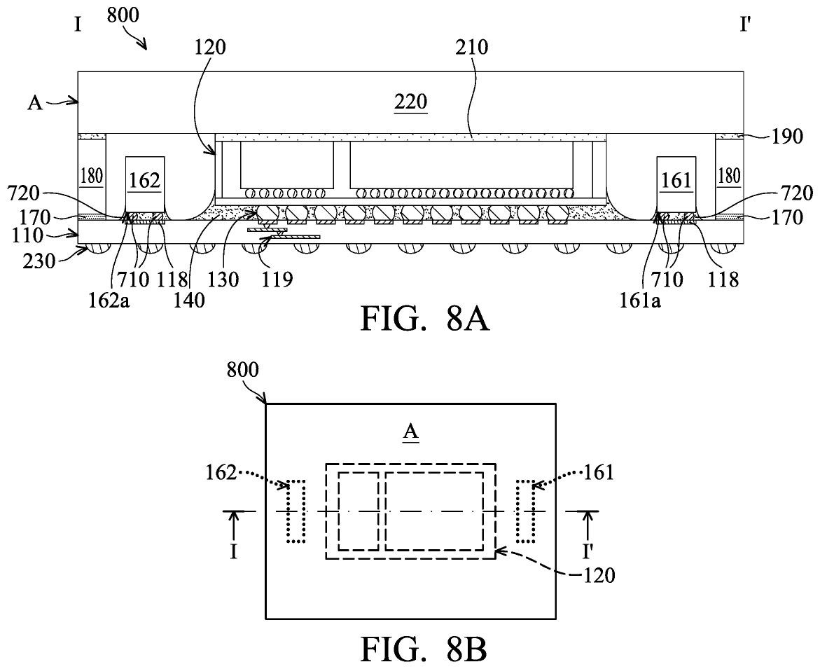

FIG. 8A is a cross-sectional view of a chip package structure 800, in accordance with some embodiments. FIG. 8B is a top view of the chip package structure 800 of FIG. 8A, in accordance with some embodiments. FIG. 8A is a cross-sectional view illustrating the semiconductor device structure 800 along a sectional line I-I′ in FIG. 8B, in accordance with some embodiments.

As shown in FIGS. 8A and 8B, the chip package structure 800 is similar to the chip package structure 200 of FIGS. 2A and 2B, except that the chip package structure 800 further includes conductive bumps 710 and an underfill layer 720 and does not include the adhesive layer 150 of the chip package structure 200, in accordance with some embodiments.

The anti-warpage structures 161 and 162 are bonded to the wiring substrate 110 through the conductive bumps 710, in accordance with some embodiments. The conductive bumps 710 are between the anti-warpage structures 161 and 162 and the wiring substrate 110, in accordance with some embodiments. The conductive bumps 710 are in contact with the semiconductor bottom surfaces 161a and 162a of the anti-warpage structures 161 and 162, in accordance with some embodiments.

The wiring substrate 110 further includes dummy bonding pads 118, in accordance with some embodiments. The conductive bumps 710 are bonded to the dummy bonding pads 118, in accordance with some embodiments. The anti-warpage structures 161 and 162 are electrically insulated from the chip package 120 and the wiring structure 119 of the wiring substrate 110, in accordance with some embodiments.

The underfill layer 720 is between the anti-warpage structure 161 and the wiring substrate 110 and between the anti-warpage structure 162 and the wiring substrate 110, in accordance with some embodiments. The underfill layer 720 surround the conductive bumps 710 and the anti-warpage structures 161 and 162, in accordance with some embodiments. The underfill layer 720 is made of an insulating material, such as a polymer material, in accordance with some embodiments.

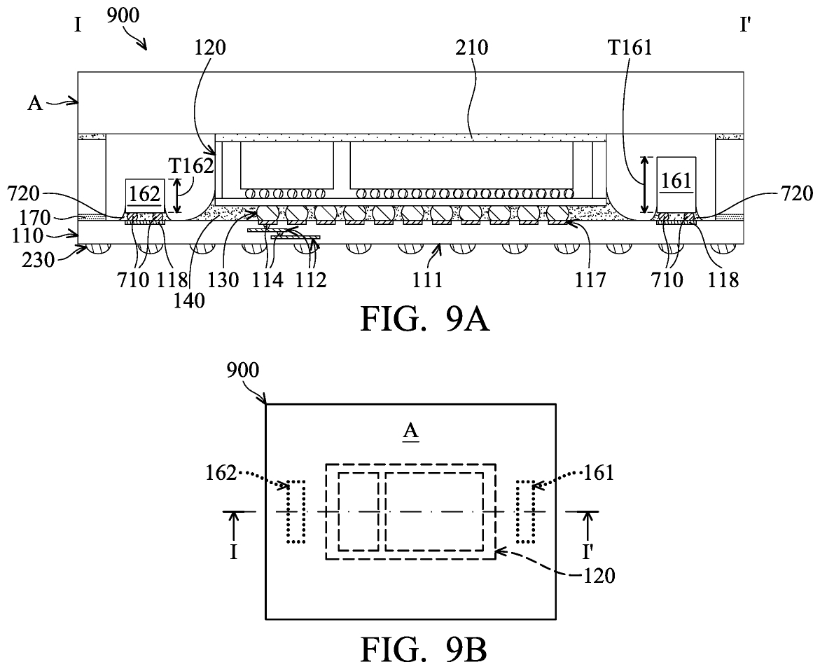

FIG. 9A is a cross-sectional view of a chip package structure 900, in accordance with some embodiments. FIG. 9B is a top view of the chip package structure 900 of FIG. 9A, in accordance with some embodiments. FIG. 9A is a cross-sectional view illustrating the semiconductor device structure 900 along a sectional line I-I′ in FIG. 9B, in accordance with some embodiments.

As shown in FIGS. 9A and 9B, the chip package structure 900 is similar to the chip package structure 800 of FIGS. 8A and 8B, except that the thickness T162 of the anti-warpage structure 162 is less than the thickness T161 of the anti-warpage structure 161 in the chip package structure 900, in accordance with some embodiments.

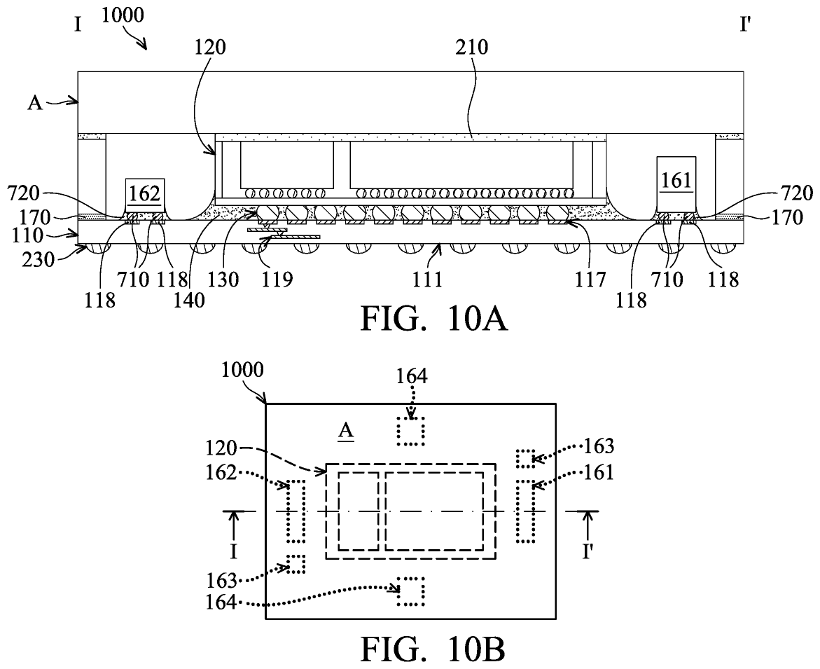

FIG. 10A is a cross-sectional view of a chip package structure 1000, in accordance with some embodiments. FIG. 10B is a top view of the chip package structure 1000 of FIG. 10A, in accordance with some embodiments. FIG. 10A is a cross-sectional view illustrating the semiconductor device structure 1000 along a sectional line I-I′ in FIG. 10B, in accordance with some embodiments.

As shown in FIGS. 10A and 10B, the chip package structure 1000 is similar to chip package structure 900 of FIGS. 9A and 9B, except that the chip package structure 1000 further includes anti-warpage structures 163 and 164, in accordance with some embodiments. The sizes of the anti-warpage structures 161 (or 162), 163, and 164 are different from each other, in accordance with some embodiments.

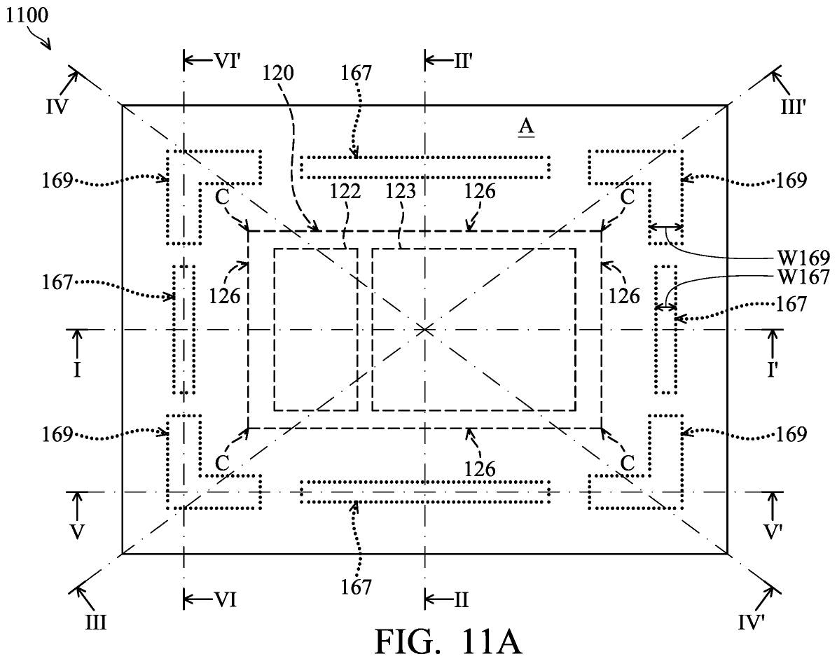

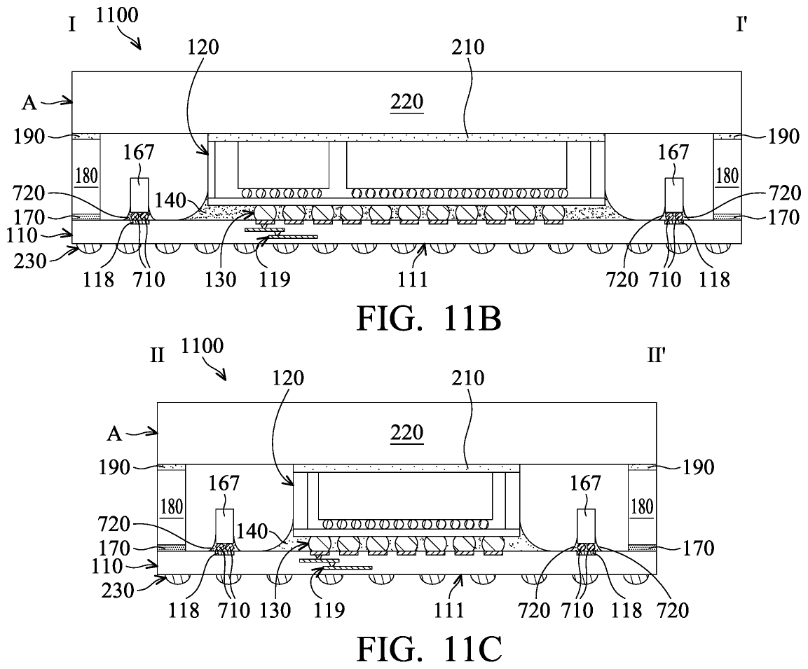

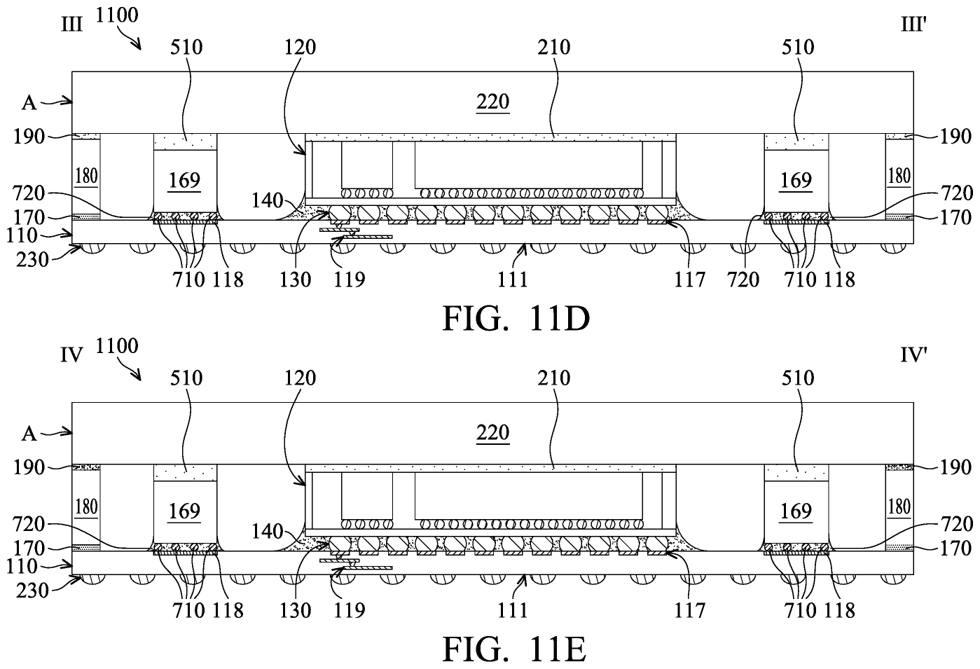

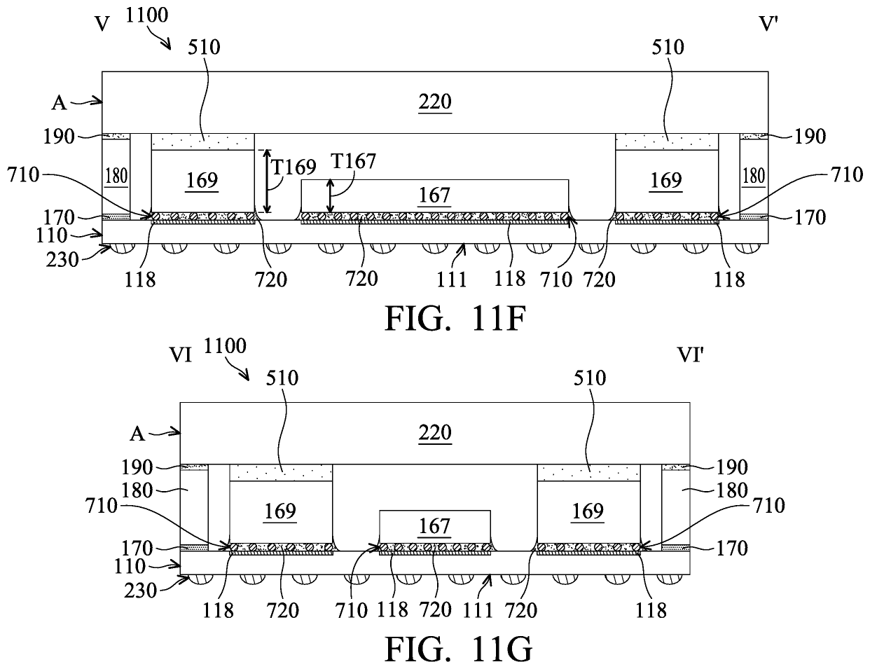

FIG. 11A is a top view of a chip package structure 1100, in accordance with some embodiments. FIG. 11B is a cross-sectional view illustrating the chip package structure 1100 along a sectional line I-I′ in FIG. 11A, in accordance with some embodiments. FIG. 11C is a cross-sectional view illustrating the chip package structure 1100 along a sectional line II-II′ in FIG. 11A, in accordance with some embodiments.

FIG. 11D is a cross-sectional view illustrating the chip package structure 1100 along a sectional line III-III′ in FIG. 11A, in accordance with some embodiments. FIG. 11E is a cross-sectional view illustrating the chip package structure 1100 along a sectional line IV-IV′ in FIG. 11A, in accordance with some embodiments.

FIG. 11F is a cross-sectional view illustrating the chip package structure 1100 along a sectional line V-V′ in FIG. 11A, in accordance with some embodiments. FIG. 11G is a cross-sectional view illustrating the chip package structure 1100 along a sectional line VI-VI′ in FIG. 11A, in accordance with some embodiments.

As shown in FIGS. 11A and 11B, the chip package structure 1100 is similar to the chip package structure 800 of FIGS. 8A and 8B, except that the chip package structure 1100 further includes anti-warpage structures 167 and 169 and an adhesive layer 510 and does not include the anti-warpage structures 161 and 162, in accordance with some embodiments.

The anti-warpage structures 167 and 169 are bonded to the wiring substrate 110 through the conductive bumps 710, in accordance with some embodiments. The underfill layer 720 is between the anti-warpage structures 167 and the wiring substrate 110 and between the anti-warpage structures 169 and the wiring substrate 110, in accordance with some embodiments. The underfill layer 720 surrounds the conductive bumps 710 and the anti-warpage structures 167 and 169, in accordance with some embodiments.

The anti-warpage structures 167 and 169 are electrically insulated from the chip package 120 and the wiring structure 119 of the wiring substrate 110, in accordance with some embodiments. The anti-warpage structures 167 and 169 are made of a material the same as the anti-warpage structures 161 of FIG. 1D, in accordance with some embodiments.

As shown in FIG. 11A, the linewidth W169 of the anti-warpage structure 169 is greater than the linewidth W167 of the anti-warpage structure 167, in accordance with some embodiments. As shown in FIGS. 11B, 11C, 11D, 11E, 11F and 11G, the thickness T169 of the anti-warpage structure 169 is greater than the thickness T167 of the anti-warpage structure 167, in accordance with some embodiments.

As shown in FIG. 11A, the chip package 120 has corner portions C and sidewalls 126, in accordance with some embodiments. The sidewalls 126 are between the corner portions C, in accordance with some embodiments. Since first portions of the wiring substrate 110 adjacent to the sidewalls 126 are originally prone to small warpage, the anti-warpage structures 167 are disposed over the first portions, in accordance with some embodiments.

The anti-warpage structure 167 is between two of the corner portions C, in accordance with some embodiments. The anti-warpage structure 167 extends along the corresponding sidewall 126, in accordance with some embodiments. The anti-warpage structures 167 are spaced apart from the chip package 120, in accordance with some embodiments.

Since second portions of the wiring substrate 110 adjacent to the corner portions C are originally prone to large warpage, the anti-warpage structures 169 are disposed over the second portions, in accordance with some embodiments. The anti-warpage structure 169 surrounds one of the corner portions C, in accordance with some embodiments. The anti-warpage structure 169 has an L-shape, in accordance with some embodiments.

The adhesive layer 510 is bonded between the anti-warpage structures 169 and the lid 220, in accordance with some embodiments. The formation of the adhesive layer 510 includes: forming the adhesive layer 510 over the anti-warpage structures 169; and bonding the lid 220 to the adhesive layer 510, in accordance with some embodiments.

The adhesive layer 510 is made of a polymer material such as epoxy or silicone, in accordance with some embodiments. The adhesive layer 510 can fix the anti-warpage structures 169 to the lid 220, which improves the anti-warpage ability of the anti-warpage structures 169, in accordance with some embodiments.

The formation of the chip package structure 1100 includes: bonding the chip package 120 to the wiring substrate 110 through the solder bumps 130; bonding the anti-warpage structures 167 and 169 to the wiring substrate 110 through the conductive bumps 710; forming the underfill layers 140 and 720 between the chip package 120 and the wiring substrate 110 and between the anti-warpage structures 167 and 169 and the wiring substrate 110; forming the adhesive layer 170 over the wiring substrate 110; disposing the ring structure 180 over the adhesive layer 170; forming the adhesive layers 190, 210 and 510 over the ring structure 180, the chip package 120, and the anti-warpage structures 169 respectively; disposing the lid 220 over the adhesive layers 190, 210 and 510; and forming the solder bumps 230 over the bottom surface 111 of the wiring substrate 110, in accordance with some embodiments.

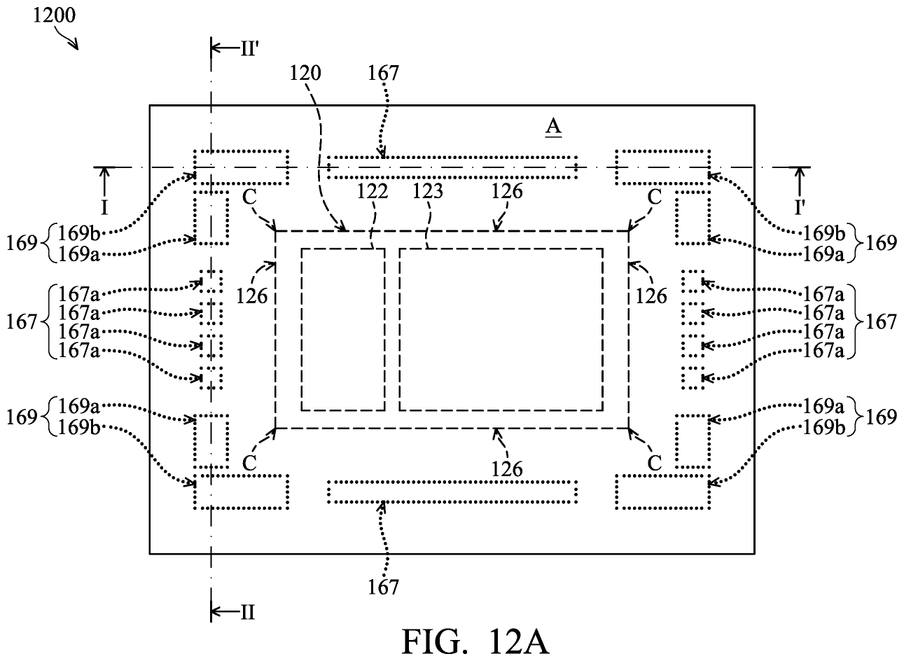

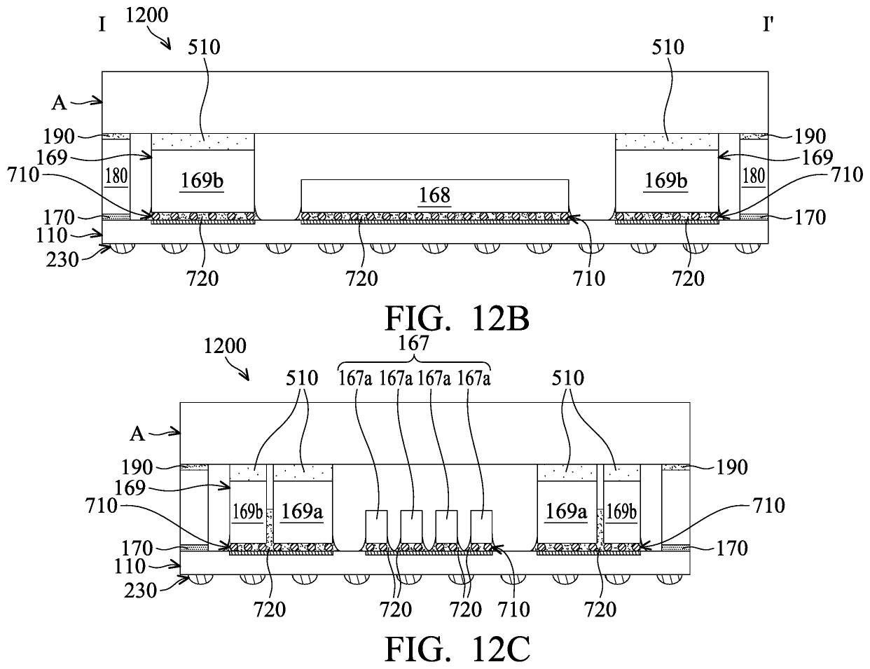

FIG. 12A is a top view of a chip package structure 1200, in accordance with some embodiments. FIG. 12B is a cross-sectional view illustrating the chip package structure 1200 along a sectional line I-I′ in FIG. 12A, in accordance with some embodiments. FIG. 12C is a cross-sectional view illustrating the chip package structure 1200 along a sectional line II-II′ in FIG. 12A, in accordance with some embodiments.

As shown in FIGS. 12A, 12B and 12C, the chip package structure 1200 is similar to the chip package structure 1100 of FIGS. 11A, 11F and 11G, except that the anti-warpage structure 167 has parts 167a, and the anti-warpage structure 169 has parts 169a and 169b in the chip package structure 1200, in accordance with some embodiments.

In one of the anti-warpage structures 167, the parts 167a are spaced apart from each other, in accordance with some embodiments. The parts 167a are arranged along the corresponding sidewall 126 of the chip package 120, in accordance with some embodiments. In one of the anti-warpage structures 169, the parts 169a and 169b are spaced apart from each other, in accordance with some embodiments.

In one of the anti-warpage structures 169, the part 169a extends along one of the sidewalls 126, the part 169b extends along another one of the sidewalls 126, and the one and the another one of the sidewalls 126 meet to form one of the corner portions C, in accordance with some embodiments.

Processes and materials for forming the chip package structures 200, 300, 400, 500, 600, 600, 700, 800, 900, 1000, 1100, and 1200 may be similar to, or the same as, those for forming the chip package structure 100 described above. Elements designated by the same reference numbers as those in FIGS. 1A to 12C have structures and materials that are the same or similar. Therefore, the detailed descriptions thereof will not be repeated herein. The anti-warpage structures 161, 162, 163, 164, 167, and 169 are semiconductor substrates and do not have devices, conductive lines, and conductive vias, in accordance with some embodiments.

In accordance with some embodiments, chip package structures and methods for forming the same are provided. The methods (for forming the chip package structure) form a first anti-warpage structure over a wiring substrate to locally reduce the warpage of the wiring substrate, which improves the coplanarity of solder bump formed under the wiring substrate. The methods further form a second anti-warpage structure over the wiring substrate and having a different size from the first anti-warpage structure. The anti-warpage abilities of the first anti-warpage structure and the second anti-warpage structure are different, which improves design flexibility.

In accordance with some embodiments, a chip package structure is provided. The chip package structure includes a wiring substrate. The chip package structure includes a chip package over and electrically connected to the wiring substrate. The chip package structure includes a first anti-warpage structure bonded to the wiring substrate. The first anti-warpage structure is made of a semiconductor material and electrically insulated from a wiring structure of the wiring substrate and the chip package. The chip package structure includes a heat dissipation structure over the wiring substrate and surrounding the chip package and the first anti-warpage structure.

In accordance with some embodiments, a chip package structure is provided. The chip package structure includes a wiring substrate. The chip package structure includes a chip package over and electrically connected to the wiring substrate. The chip package structure includes a first anti-warpage structure bonded to the wiring substrate. The first anti-warpage structure is electrically insulated from the chip package. The chip package structure includes a second anti-warpage structure bonded to the wiring substrate. The second anti-warpage structure is electrically insulated from the chip package and the first anti-warpage structure, and the second anti-warpage structure is thinner than the first anti-warpage structure. The chip package structure includes a heat dissipation structure over the wiring substrate and surrounding the chip package, the first anti-warpage structure, and the second anti-warpage structure.

In accordance with some embodiments, a method for forming a chip package structure is provided. The method includes bonding a chip package to a wiring substrate. The method includes bonding a first anti-warpage structure to the wiring substrate. The first anti-warpage structure is made of a semiconductor material and electrically insulated from the chip package and a wiring structure of the wiring substrate. The method includes bonding a heat dissipation structure to the wiring substrate. The heat dissipation structure surrounds the chip package and the first anti-warpage structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package structure, comprising:
a wiring substrate;
a chip package over and electrically connected to the wiring substrate;
a first anti-warpage structure bonded to the wiring substrate, wherein the first anti-warpage structure is made of a semiconductor material and electrically insulated from a wiring structure of the wiring substrate and the chip package; and
a heat dissipation structure over the wiring substrate and surrounding the chip package and the first anti-warpage structure.

2. The chip package structure as claimed in claim 1, further comprising:
an adhesive layer between the first anti-warpage structure and the wiring substrate.

3. The chip package structure as claimed in claim 1, further comprising:
a second anti-warpage structure bonded to the wiring substrate, wherein the second anti-warpage structure is made of the semiconductor material and electrically insulated from the wiring structure of the wiring substrate, the chip package, and the first anti-warpage structure, and the heat dissipation structure further surrounds the second anti-warpage structure.

4. The chip package structure as claimed in claim 3, wherein the first anti-warpage structure is thicker than the second anti-warpage structure.

5. The chip package structure as claimed in claim 4, wherein the first anti-warpage structure is wider than the second anti-warpage structure.

6. The chip package structure as claimed in claim 5, wherein the first anti-warpage structure surrounds a first corner portion of the chip package.

7. The chip package structure as claimed in claim 6, wherein the chip package has a sidewall, the first corner portion and a second corner portion of the chip package are on opposite sides of the sidewall, the second anti-warpage structure is between the first corner portion and the second corner portion and extends along the sidewall, and the second anti-warpage structure is spaced apart from the chip package.

8. The chip package structure as claimed in claim 6, wherein the first anti-warpage structure has an L-shape.

9. The chip package structure as claimed in claim 5, wherein the heat dissipation structure has a lid covering the chip package and the first anti-warpage structure, and the chip package structure further comprises:
an adhesive layer between the first anti-warpage structure and the lid.

10. The chip package structure as claimed in claim 4, wherein the heat dissipation structure covers the chip package and the first anti-warpage structure, and the chip package structure further comprises:
an adhesive layer between the first anti-warpage structure and the heat dissipation structure.

11. The chip package structure as claimed in claim 1, further comprising:
a first conductive bump between the first anti-warpage structure and the wiring substrate, wherein the first conductive bump is in contact with a semiconductor bottom surface of the first anti-warpage structure.

12. The chip package structure as claimed in claim 11, further comprising:
a second conductive bump between the first anti-warpage structure and the wiring substrate, wherein the second conductive bump is in contact with the semiconductor bottom surface, the wiring substrate comprises a dummy bonding pad, and the first conductive bump and the second conductive bump are bonded to the dummy bonding pad.

13. A chip package structure, comprising:
a wiring substrate;
a chip package over and electrically connected to the wiring substrate;
a first anti-warpage structure bonded to the wiring substrate, wherein the first anti-warpage structure is electrically insulated from the chip package;
a second anti-warpage structure bonded to the wiring substrate, wherein the second anti-warpage structure is electrically insulated from the chip package and the first anti-warpage structure, and the second anti-warpage structure is thinner than the first anti-warpage structure; and
a heat dissipation structure over the wiring substrate and surrounding the chip package, the first anti-warpage structure, and the second anti-warpage structure.

14. The chip package structure as claimed in claim 13, wherein the second anti-warpage structure is narrower than the first anti-warpage structure.

15. A method for forming a chip package structure, comprising:
bonding a chip package to a wiring substrate;
bonding a first anti-warpage structure to the wiring substrate, wherein the first anti-warpage structure is made of a semiconductor material and electrically insulated from the chip package and a wiring structure of the wiring substrate; and
bonding a heat dissipation structure to the wiring substrate, wherein the heat dissipation structure surrounds the chip package and the first anti-warpage structure.

16. The method for forming the chip package structure as claimed in claim 15, further comprising:
forming an adhesive layer over the first anti-warpage structure, wherein the heat dissipation structure has a lid, and the adhesive layer is bonded to the lid after the heat dissipation structure is bonded to the wiring substrate.

17. The method for forming the chip package structure as claimed in claim 15, wherein the bonding of the first anti-warpage structure to the wiring substrate comprises:
bonding the first anti-warpage structure to the wiring substrate through a first conductive bump, wherein the first conductive bump is bonded to a dummy bonding pad of the wiring substrate.

18. The method for forming the chip package structure as claimed in claim 17, wherein the bonding of the first anti-warpage structure to the wiring substrate further comprises:
bonding the first anti-warpage structure to the wiring substrate through a second conductive bump, wherein the second conductive bump is bonded to the dummy bonding pad of the wiring substrate.

19. The method for forming the chip package structure as claimed in claim 15, further comprising:
bonding a second anti-warpage structure to the wiring substrate, wherein the second anti-warpage structure is made of the semiconductor material and electrically insulated from the chip package and the wiring structure of the wiring substrate, and the second anti-warpage structure is thinner than the first anti-warpage structure.

20. The method for forming the chip package structure as claimed in claim 19, wherein the second anti-warpage structure is narrower than the first anti-warpage structure.
